(19) United States
(12) Patent Application Publication
(10) Pub. No.: US 2023/0012678 A1
(43) Pub. Date: Jan. 19, 2023

(54) OPTO-ELECTRIC HYBRID BOARD AND OPTO-ELECTRIC COMPOSITE TRANSMISSION MODULE

(71) Applicant: NITTO DENKO CORPORATION, Osaka (JP)

(72) Inventors: Kazuaki SUZUKI, Osaka (JP); Naoyuki TANAKA, Osaka (JP); Naoto KONEGAWA, Osaka (JP)

(73) Assignee: NITTO DENKO CORPORATION, Osaka (JP)

(21) Appl. No.: 17/797,629

(22) PCT Filed: Feb. 5, 2021
(86) PCT No.: PCT/JP2021/004314

§ 371 Date: Aug. 4, 2022

(30) Foreign Application Priority Data
Feb. 12, 2020 (JP) 2020-021650

(51) Int. Cl. G02B 6/42

(52) U.S. Cl. CPC G02B 6/4268

(57) ABSTRACT

An opto-electric hybrid board includes an optical waveguide extending in the longitudinal direction and an electric circuit board disposed on a one-side surface in the thickness direction of the optical waveguide and extending in the longitudinal direction. The electric circuit board includes a first terminal disposed in a one end portion in the longitudinal direction of a one-side surface in the thickness direction of the electric circuit board and being for mounting the optical element, and a second terminal disposed in the one end portion in the longitudinal direction of the one-side surface in the thickness direction of the electric circuit board and being for mounting a driver element electrically connected with the optical element. The electric circuit board has one edge in the longitudinal direction at one side in the longitudinal direction as compared to one edge in the longitudinal direction of the optical waveguide.

The present invention relates to an opto-electric hybrid board and an opto-electric composite transmission module.

### BACKGROUND ART

Conventionally, an opto-electric composite transmission module that includes an opto-electric hybrid board extending in the longitudinal direction and a photonic device mounted on the one-side surface in the thickness direction of the one end portion in the longitudinal direction of the opto-electric hybrid board has been known (for example, see Patent document 1 below).

In the opto-electric composite transmission module of Patent document 1, the opto-electric hybrid board includes an optical waveguide and an electric circuit board sequentially toward one side in the thickness direction. In the opto-electric hybrid board, the one edge of the optical waveguide corresponds to the one edge of the electric circuit board.

### CITATION LIST

### Patent Document

Patent Document 1: Japanese Unexamined Patent Publication No. 2018-151570

### SUMMARY OF THE INVENTION

### Problem to be Solved by the Invention

However, the optical element is adjacent to the driver element mounted on the one-side surface in the thickness direction of the one end portion in the longitudinal direction of the opto-electric hybrid board. The electric circuit board includes terminals on which the above-described elements are mounted.

The optical element is electrically connected with the driver element and optically functions based on the driving of the driver element. However, the driver element generates a lot of heat in operation. The generated heat is first transmitted to the electric circuit board toward the other side in the thickness direction, and then dissipated through the optical waveguide.

However, the optical waveguide is generally made of a resin material and has a low thermal conductivity. Thus, the above-described heat cannot efficiently be dissipated, and there is a disadvantage that the heat of the driver element affects the optical element before the dissipation and thus reduces the function of the optical element.

The present invention provides an opto-electric hybrid board and an opto-electric composite transmission module, both of which can efficiently dissipate the heat generated by the driver element and suppress the reduction in the function of the optical element.

### Means for Solving the Problem

The present invention [1] includes an opto-electric hybrid board comprising: an optical waveguide extending in a longitudinal direction; and an electric circuit board disposed on a one-side surface in a thickness direction of the optical waveguide and extending in the longitudinal direction, the electric circuit board including a first terminal disposed on a one end portion in the longitudinal direction of a one-side surface in the thickness direction of the electric circuit board, the first terminal being for mounting an optical element, and a second terminal disposed on the one end portion in the longitudinal direction of the one-side surface in the thickness direction of the electric circuit board, the second terminal being for mounting a driver element electrically connected with the optical element, wherein one edge in the longitudinal direction of the electric circuit board is located at one side in the longitudinal direction as compared to one edge in the longitudinal direction of the optical waveguide.

In the opto-electric hybrid board, the driver element is mounted on the one end portion in the longitudinal direction of the electric circuit board. When the driver element generates heat, the heat first reaches the electric circuit board. The one edge in the longitudinal direction of the electric circuit board is located at one side in the longitudinal direction as compared to the one edge in the longitudinal-direction of the optical waveguide. The heat can be released to the other side in the thickness direction without the intervention of the optical waveguide. Thus, the reduction in the function of the optical element can be suppressed.

The present invention [2] includes the opto-electric hybrid board described in [1], wherein the electric circuit board includes a metal supporting layer in the one end portion in the longitudinal direction of the electric circuit board, and one edge in the longitudinal direction of the metal supporting layer at one side in the longitudinal direction as compared to the one edge in the longitudinal direction of the optical waveguide

In the opto-electric hybrid board, the electric circuit board includes the metal supporting layer, and the one edge in the longitudinal direction of the metal supporting layer is located at one side in the longitudinal direction as compared to the one edge in the longitudinal direction of the optical waveguide. Thus, the heat reaching the metal supporting board from the driver element can efficiently be released.

The present invention [3] includes an opto-electric transmission composite module comprising: the opto-electric hybrid board described in [1] or [2]; and a heat dissipating layer being in contact with the other-side surface in the thickness direction of the electric circuit board located at one side in the longitudinal direction as compared to the one edge in the longitudinal direction of the optical waveguide.

In the opto-electric transmission composite module, the heat dissipating layer is in contact with the other-side surface in the thickness direction of the electric circuit board located at one side in the longitudinal direction as compared to the one edge in the longitudinal-direction of the optical waveguide. Thus, the heat dissipating layer can efficiently release the heat reaching the electric circuit board from the driver element.

### Effects of the Invention

The opto-electric hybrid board and opto-electric composite transmission module of the present invention efficiently release the heat generated by the driver element and can suppress the reduction in the function of the optical element.

### BRIEF DESCRIPTION OF THE DRAWINGS

FIG. 1 is an enlarged cross-sectional view of a one end portion in the longitudinal direction of one embodiment of the opto-electric transmission composite module of the present invention.

FIGS. 2A-2D illustrate the steps of producing the opto-electric transmission composite module of FIG. 1. FIG. 2A illustrates a step of forming an electric circuit board. FIG. 2B illustrates a step of forming an optical waveguide. FIG. 2C illustrates a step of disposing an optical element and a driver element. FIG. 2D illustrates a step of preparing a first wall and a heat dissipating layer.

FIG. 3 illustrates a variation of the opto-electric transmission composite module of FIG. 1 (an opto-electric transmission composite module where the electric circuit board does not include a metal supporting layer).

FIG. 4 illustrates a variation of the opto-electric transmission composite module of FIG. 1 (an opto-electric transmission composite module that does not include a heat dissipating layer).

FIG. 5 illustrates a variation of the opto-electric transmission composite module of FIG. 1 (where the electric circuit board does not include a metal supporting layer and the opto-electric transmission composite module does not include a heat dissipating layer).

### DESCRIPTION OF THE EMBODIMENTS

### One Embodiment

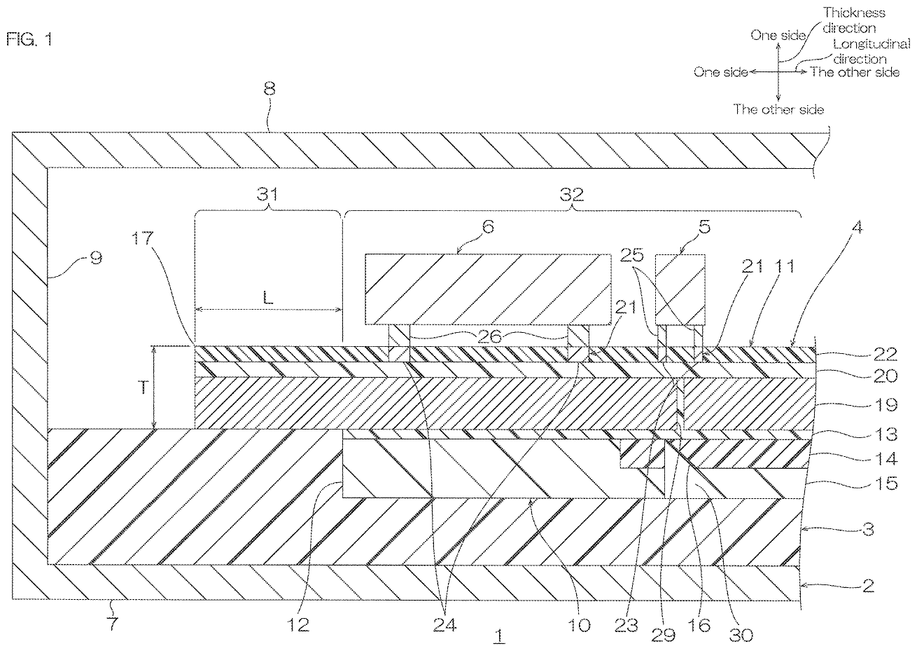

One embodiment of the opto-electric transmission composite module of the present invention is described with reference to FIG. 1.

An opto-electric transmission composite module 1 has a predetermined thickness and has a shape extending in a longitudinal direction. The opto-electric transmission composite module 1 converts received light into electricity and transmits the electricity, and converts received electricity into light and transmits the light. The opto-electric transmission composite module 1 includes a casing 2, a heat dissipating layer 3, an opto-electric hybrid board 4, an optical element 5, and a driver element 6.

The casing 2 has an approximately flat box shape with a length in a width direction (orthogonal to the thickness direction and the longitudinal direction) and a length in the thickness direction that is smaller than the length in the width direction. The casing 2 integrally includes at least a first wall 7, a second wall 8, a first coupling wall 9, a second coupling wall not illustrated, and both side walls not illustrated.

The first wall 7 has a board shape extending along the longitudinal direction.

The second wall 8 faces the first wall 7, is disposed at one side in the thickness direction of the first wall 7, and separated from the first wall 7 by an interval. The second wall 8 has a shape identical to that of the first wall 7.

The first coupling wall 9 couples one edge in the longitudinal direction of the first wall 7 with one edge in the longitudinal direction of the second wall 8 in the thickness direction. The first coupling wall 9 has a board shape extending in the width direction.

The second coupling wall not illustrated couples the other edge in the longitudinal direction of the first wall 7 with the other edge in the longitudinal direction of the second wall 8 in the thickness direction. The second coupling wall extends in the width direction and has a shape identical to that of the coupling wall 9.

Both the side walls couple one edge in the width direction of the first wall 7 with one edge in the width direction of the second wall 8 in the thickness direction, and the other edge in the width direction of the first wall 7 with the other edge in the width direction of the second wall 8 in the thickness direction. Further, both the side walls continue to both edges in the width direction of the first coupling wall 9 and both edges in the width direction of the second coupling wall not illustrated. Both the side walls each extend in the longitudinal direction.

Examples of the material of the casing 2 include metals to ensure excellent thermal dissipation. Examples of the metals include aluminum, copper, silver, zinc, nickel, chromium, titanium, tantalum, platinum, gold, and alloys thereof (bronze alloys or stainless steels).

The heat dissipating layer 3 has a predetermined thickness and has a shape extending in the longitudinal direction. The heat dissipating layer 3 is accommodated in the casing 2. Specifically, the heat dissipating layer 3 is in contact with a one-side surface in the thickness direction of the first wall 7. Examples of the heat dissipating layer 3 include heat dissipating sheets, heat dissipating greases, and heat dissipating boards. Examples of the material of the heat dissipating sheet include fillers such as alumina (aluminum oxide), boron nitride, zinc oxide, aluminum hydroxide, molten silica, magnesium oxide, and aluminum nitride, and filler resin compositions in which a filler is dissolved in a resin, such as a silicone resin, an epoxy resin, an acrylic resin, or a urethane resin. For example, the filler may be inclined with respect to the resin in the thickness direction in the heat dissipating sheet. The resin may contain a thermosetting resin and may be in B stage or C stage. The resin can contain a thermoplastic resin. The heat dissipating sheet has an Asker C hardness at 23° C. of, for example, less than 60, preferably 50 or less, more preferably 40, and, for example, 1 or more. The Asker C hardness of the heat dissipating layer 3 is obtained using an Asker rubber hardness tester C type.

The heat dissipating layer 3 has a thermal conductivity in the thickness direction of, for example, 3 W/m K or more, preferably 10 W/m K or more, more preferably 20 W/m K or more, and, for example, 200 W/m K or less. The thermal conductivity of the heat dissipating layer 3 is obtained by a steady-state method in conformity to ASTM-D5470, or by a hot disk method in conformity to ISO-22007-2.

The opto-electric hybrid board 4 is accommodated in the casing 2. The opto-electric hybrid board 4 has a predetermined thickness and has a board shape extending in the longitudinal direction. Specifically, the opto-electric hybrid board 4 is in contact with a one-side surface in the thickness direction of the heat dissipating layer 3. The opto-electric hybrid board 4 includes an optical waveguide 10 and an electric circuit board 11 toward the one side in the thickness direction.

The optical waveguide 10 has a predetermined thickness and a shape extending along the longitudinal direction. The optical waveguide 10 includes an under-cladding layer 13, a core layer 14, and an over-cladding layer 15.

The under-cladding layer 13 has a shape identical to the shape of the optical waveguide 10 in a plan view.

The core layer 14 is disposed in an intermediate portion in the width direction of the other-side surface in the thickness direction of the under-cladding layer 13. The core layer 14 has a width smaller than the width of the under-cladding layer 13 in the plan view.

The over-cladding layer 15 is disposed on the other-side surface in the thickness direction of the under-cladding layer 13 to cover the core layer 14. The over-cladding layer 15 has a shape identical to an outer shape of the under-cladding layer 13 in the plan view. Specifically, the over-cladding layer 15 is disposed on the other-side surface in the thickness direction of the core layer 14 and both side surfaces in the width direction of the core layer 14, and on both outside parts in the width direction of the core layer 14 on the other-side surface in the thickness direction of the under-cladding layer 13. The over-cladding layer 15 is in contact with the heat dissipating layer 3.

A mirror 16 is formed in a one end portion in the longitudinal direction of the core layer 14.

Examples of the material of the optical waveguide 10 include transparent materials such as epoxy resins. The core layer 14 has a higher refractive index than each of the refractive index of the under-cladding layer 13 and the refractive index of the over-cladding layer 15. The optical waveguide 10 has a thickness of, for example, 20 μm or more, and, for example, 200 μm or less.

The electric circuit board 11 has a shape identical to that of the opto-electric hybrid board 4 in the plan view. In other words, the electric circuit board 11 has a predetermine thickness and has a board shape extending in the longitudinal direction. The electric circuit board 11 is disposed at one side in the thickness direction of the optical waveguide 10. The electric circuit board 11 includes a first region 31 and a second region 32 in a one end portion in the longitudinal direction of the electric circuit board 11.

The first region 31 is a region that includes one edge 17 in the longitudinal direction of the electric circuit board 11 and the other-side part in the longitudinal direction of the one edge 17 in the longitudinal direction. The first region 31 is unaligned with the optical waveguide 10 when being projected from the thickness direction. The first region 31 is a non-overlap region that does not overlap the optical waveguide 10 when being projected in the thickness direction. Thus, the other-side surface in the thickness direction of the first region 31 is not in contact with the optical waveguide 10 and, in one embodiment, is in contact with the heat dissipating layer 3. The one edge 17 in the longitudinal direction of the electric circuit board 11 included in the first region 31 corresponds to one edge 17 in the longitudinal direction of the opto-electric hybrid board 4.

The first region 31 has a length L of, for example, 10 μm or more, preferably 100 μm or more, more preferably 1,000 μm or more, and, for example, 1,000,000 μm or less in the longitudinal direction. A ratio (L/T) of the length L to a thickness T of the electric circuit board 11 is, for example, 1 or more, preferably 10 or more, more preferably 100 or more, and, for example, 10,000 or less. When the length L of the first region 31 and/or the ratio (L/T) are/is the above-described lower limit(s) or more, the heat transmitted to the opto-electric hybrid board 4 can efficiently be released.

The second region 32 is a region that is located continuously to the other side in the longitudinal direction of the first region 31. When being projected in the thickness direction, the second region 32 overlaps the optical waveguide 10. Thus, the second region 32 is an overlap region that overlaps the optical waveguide 10. Consequently, the other-side surface in the thickness direction of the second region 32 is in contact with the under-cladding layer 13 of the optical waveguide 10. Consequently, the longitudinal-direction one edge 17 included in the first region 31 of the electric circuit board 11 is located at one side in the longitudinal direction as compared to one edge 12 in the longitudinal direction of the optical waveguide 10 that overlaps the second region 32 of the electric circuit board 11. In other words, the one edge 17 in the longitudinal direction of the electric circuit board 11 is located at one side in the longitudinal direction as compared to the one edge 12 in the longitudinal direction of the optical waveguide 10.

The electric circuit board 11 includes a metal supporting layer 19, an insulating base layer 20, a conductive layer 21, and an insulating cover layer 22.

The metal supporting layer 19 has an outer shape identical to that of the opto-electric hybrid board 4 in the plan view. The optical waveguide 10 is an outermost part at the other side in the thickness direction of the opto-electric hybrid board 4. The metal supporting layer 19 is provided across the first region 31 and the second region 32. One edge 17 in the longitudinal direction of the metal supporting layer 19 corresponds to the one edge 17 in the longitudinal direction of the electric circuit board 11 in the thickness direction. Thus, the one edge 17 in the longitudinal direction of the metal supporting layer 19 is located at one side in the longitudinal direction as compared to the one edge 12 in the longitudinal direction of the optical waveguide 10.

The other-side surface in the thickness direction of the metal supporting layer 19 in the first region 31 is in contact with the heat dissipating layer 3.

The other-side surface in the thickness direction of the metal supporting layer 19 in the second region 32 is in contact with the under-cladding layer 13. A through-hole 29 that penetrates the metal supporting layer 19 in the thickness direction is formed in the metal supporting layer 19 in the second region 32. When being projected in the thickness direction, the through-hole 29 overlaps the mirror 16. The metal supporting layer 19 has an inside surface that defines the through-hole 29 and is in contact with the under-cladding layer 13.

Examples of the material of the metal supporting layer 19 include metals such as stainless steels, 42 alloys, copper-beryllium, phosphor bronze, copper, silver, aluminum, nickel, chromium, titanium, tantalum, platinum, and gold. To achieve excellent thermal conductivity, copper and a stainless steel are preferable. The metal supporting layer 19 has a thickness of, for example, 3 μm or more, preferably 10 μm or more, and, for example, 100 μm or less, preferably 50 μm or less.

The insulating base layer 20 has an outer shape identical to that of the metal supporting layer 19 in the plan view. The insulating base layer 20 is provided across the first region 31 and the second region 32. The insulating base layer 20 has one edge 17 in the longitudinal direction that corresponds to the one edge 17 in the longitudinal direction of the electric circuit board 11 in the thickness direction. The insulating base layer 20 is disposed on a one-side surface in the thickness direction of the metal supporting layer 19. Specifically, the other-side surface in the thickness direction of the insulating base layer 20 is in contact with the one-side surface in the thickness direction of the metal supporting layer 19. Further, the insulating base layer 20 blocks one edge in the thickness direction of the through-hole 29. Examples of the material of the insulating base layer 20 include resins such as polyimide. The insulating base layer 20 has a thickness of, for example, 5 μm or more, and, for example, 50 μm or less, in view of thermal dissipation, preferably 40 μm or less, more preferably 30 μm or less.

The conductive layer 21 is disposed on a one-side surface in the thickness direction of the insulating base layer 20. The conductive layer 21 includes a first terminal 23, and a second terminal 24, and a wire (not illustrated).

For example, the conductive layer 21 is disposed in the second region 32.

The first terminal 23 is provided, corresponding to the optical element 5. In other words, the optical element 5 is mounted on the first terminal 23.

The second terminal 24 is provided, corresponding to the driver element 6. In other words, the driver element 6 is mounted on the second terminal 24.

The wire not illustrated couples the first terminal 23 and the second terminal 24. The wire not illustrated includes a power source wire that can be connected with an external board.

Examples of the material of the conductive layer 21 include conductors such as copper. The conductive layer 21 has a thickness of, for example, 3 μm or more, and, for example, 20 μm or less.

The insulating cover layer 22 is disposed on the one-side surface in the thickness direction of the insulating base layer 20. The insulating cover layer 22 is provided across the first region 31 and the second region 32. The insulating cover layer 22 has one edge 17 in the longitudinal direction that corresponds to the one edge 17 in the longitudinal direction of the electric circuit board 11 in the thickness direction. The insulating cover layer 22 covers the wire not illustrated while exposing the first terminal 23 and the second terminal 24. Specifically, the insulating cover layer 22 is in contact in a one-side surface in the thickness direction of the wire not illustrated and a peripheral side surface of the wire not illustrated, a peripheral side surface of the first terminal 23, a peripheral side surface of the second terminal 24, and the one-side surface in the thickness direction of the insulating base layer 20 around the conductive layer 21. Examples of the material of the insulating cover layer 22 include resins such as polyimide. The insulating cover layer 22 has a thickness of, for example, 5 μm or more, and, for example, 50 μm or less, in view of thermal dissipation, preferably 40 μm or less, more preferably 30 μm or less.

The electric circuit board 11 has a thickness T of, for example, 25 μm or more, preferably 50 μm or more, and, for example, 200 μm or less, preferably 100 μm or less.

Both of the optical element 5 and the driver element 6 are disposed (mounted) at one side in the thickness direction of the second region 32 in the opto-electric hybrid board 4.

The optical element 5 is disposed at one side in the thickness direction of the insulating cover layer 22 to overlap the through-hole 29 in the plan view. Examples of the optical element 5 include a light-emitting element that converts electricity into light, specifically a vertical-external-cavity surface-emitting-laser (VECSEL). Further, examples of the optical element 5 include a light-receiving element that converts light into electricity, specifically a photodiode (PD). These can be used singly or in combination.

The optical element 5 has a rectangular shape in the cross-sectional view, and include a plurality of optical bumps 25 on the other-side surface in the thickness direction of the optical element 5. The optical bumps 25 extend along the thickness direction and face the first terminal 23 in the thickness direction. The optical element 5 has an incoming and outgoing port not illustrated between the optical bumps 25 on the other-side surface in the thickness direction of the optical element 5. The incoming and outgoing port overlaps the through-hole 29 when being projected in the thickness direction.

The driver element 6 is disposed adjacently to the one side in the thickness direction of the insulating cover layer 22 and to one side in the longitudinal direction of the optical element 5. The driver element 6 is electrically connected through the conductive layer 21 to the optical element 5. Examples of the driver element 6 include drive integrated circuits and impedance converting amplifier circuits. These can be used singly or in combination. The driver element 6 has a rectangular shape in the cross-sectional view and includes a plurality of driving bumps 26 on the other-side surface in the thickness direction of the driver element 6. The driving bumps 26 extend along the thickness direction and face the second terminal 24 in the thickness direction. The driver element 6 drives the optical element 5 or conditions the electrical signal transmitted from the optical element 5. In the present embodiment, the driver element 6 is allowed to generate a lot of heat during such operation.

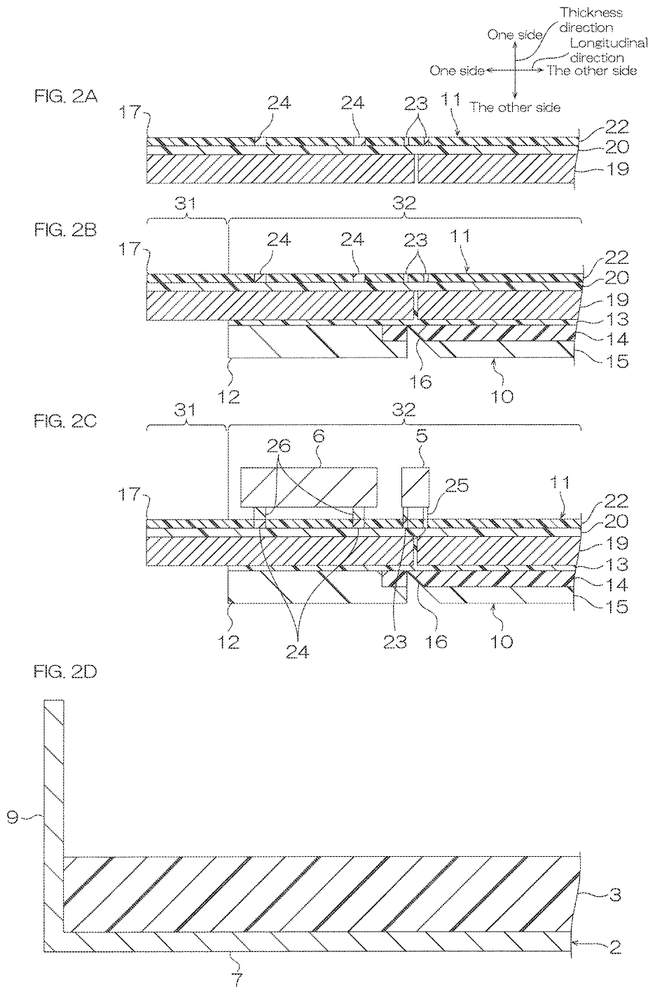

Next, a method of producing the opto-electric transmission composite module 1 is described with reference to FIG. 1 to FIG. 2D.

As illustrated in FIG. 2A, in this method, the electric circuit board 11 is produced first. For example, a metal sheet not illustrated is prepared. The insulating base layer 20, the conductive layer 21, and the insulating cover layer 22 are sequentially formed at the one side in the thickness direction of the metal sheet by a known method. Thereafter, an outer shape of the metal sheet not illustrated is processed to form the metal supporting layer 19. In this manner, the electric circuit board 11 including the metal supporting layer 19, the insulating base layer 20, the conductive layer 21, and the insulating cover layer 22 is produced.

As illustrated in FIG. 2B, in this method, the optical waveguide 10 is subsequently produced to be incorporated in the electric circuit board 11 in the second region 32.

For example, a photosensitive resin composition containing the material of the under-cladding layer 13 is applied to the whole of the other-side surface in the thickness direction of the electric circuit board 11 to form a photosensitive film. Thereafter, the photosensitive film is subjected to photolithography to form the under-cladding layer 13. The under-cladding layer 13 has one edge 12 in the longitudinal direction that is located at the other side in the longitudinal direction as compared to the one edge 17 in the longitudinal direction of the electric circuit board 11.

Subsequently, a photosensitive resin composition containing the material of the core layer 14 is applied to the other-side surface in the thickness direction of the under-cladding layer 13 and the other-side surface in the thickness direction of the electric circuit board 11 exposed from the under-cladding layer 13 (i.e., the electric circuit board 11 in the first region 31) to form a photosensitive film. Thereafter, the photosensitive film is subjected to photolithography to form the core layer 14. The core layer 14 has one edge 12 in the longitudinal direction that is located at the other side in the longitudinal direction as compared to the one edge 17 in the longitudinal direction of the electric circuit board 11.

Thereafter, a photosensitive resin composition containing the material of the over-cladding layer 15 is applied to the other-side surfaces in the thickness direction of the under-cladding layer 13 and core layer 14, and the other-side surface in the thickness direction of the electric circuit board 11 exposed from the under-cladding layer 13 (i.e., the electric circuit board 11 in the first region 31) to form a photosensitive film. Thereafter, the photosensitive film is subjected to photolithography to form the over-cladding layer 15. The over-cladding layer 15 has one edge 12 in the longitudinal direction that is located at the other side in the longitudinal direction as compared to the one edge 17 in the longitudinal direction of the electric circuit board 11.

Subsequently, the one end portion in the longitudinal direction of the core layer 14 is cut, thereby forming the mirror 16.

In this manner, as illustrated in FIG. 2B, the opto-electric hybrid board 4 including the optical waveguide 10 and the electric circuit board 11 is produced. The optical element 5 and the driver element 6 are not mounted on the opto-electric hybrid board 4 yet. The opto-electric hybrid board 4 is not disposed on the casing 2 and the heat dissipating layer 3 yet. However, the opto-electric hybrid board 4 can be distributed as a single component and is an industrially-available device.

Subsequently, as illustrated in FIG. 2C, the optical element 5 and the driver element 6 are mounted on the electric circuit board 11. For example, the optical bumps 25 made of gold are disposed on the one-side surface in the thickness direction of the first terminal 23 and connected to the first terminal 23, for example, by ultrasonic jointing. In this manner, the optical element 5 is mounted on the electric circuit board 11. For example, the driving bumps 26 made of gold are disposed on the one-side surface in the thickness direction of the second terminal 24 and connected to the second terminal 24, for example, by ultrasonic jointing. In this manner, the driver element 6 is mounted on the electric circuit board 11.

As illustrated in FIG. 2D, thereafter, the first wall 7, the first coupling wall 9, the second coupling wall not illustrated and both the side walls not illustrated are separately prepared. Subsequently, the heat dissipating layer 3 is disposed on the one-side surface in the thickness direction of the first wall 7.

As illustrated in FIG. 1, subsequently, the opto-electric hybrid board 4 is pressed to the one-side surface in the thickness direction of the heat dissipating layer 3. In this manner, when the heat dissipating layer 3 contains a resin, the heat dissipating layer 3 conforms with the other-side surface in the thickness direction of the opto-electric hybrid board 4. Consequently, the heat dissipating layer 3 is in contact with the other-side surface in the thickness direction of the electric circuit board 11 (the metal supporting layer 19) in the first region 31 and the other-side surface in the thickness direction of the optical waveguide 10 in the second region 32. The heat dissipating layer 3 is in contact also with a one end surface in the longitudinal direction of the optical waveguide 10.

The opto-electric hybrid board 4 is pressed to the heat dissipating layer 3 to the extent that the space 30 defining the mirror 16 is maintained.

Thereafter, as illustrated in FIG. 1, the second wall 8 is fixed to the first coupling wall 9, the second coupling wall (not illustrated), and both the side walls. In this manner, the casing 2 is produced. The casing 2 accommodates the heat dissipating layer 3, the opto-electric hybrid board 4, the optical element 5, and the driver element 6.

In this manner, the opto-electric transmission composite module 1 including the casing 2, the heat dissipating layer 3, the opto-electric hybrid board 4, the optical element 5, and the driver element 6 is produced.

In the opto-electric transmission composite module 1, when the optical element 5 includes a light-emitting element and the driver element 6 includes a drive integrated circuit, a power source current is input from the external board through the power source wire to the driver element 6 and the driver element 6 drives the optical element 5. Then, the optical element 5 emits light toward the mirror 16, and the light is transmitted along the core layer 14 toward the other side in the longitudinal direction.

On the other hand, when the optical element 5 includes a light-receiving element and the driver element 6 includes an impedance converting amplifier circuit, the light transmitted from the other end portion in the longitudinal direction of the core layer 14 enters from the mirror 16 to the optical element 5 and the optical element 5 generates a weak electrical signal. Then, the electrical signal is conditioned by the driver element 6 and input to the external board.

When the driver element 6 generates heat during the above-described operation of the driver element 6, the heat is released from the electric circuit board 11 in the first region 31 through the heat dissipating layer 3 to the first wall 7.

### Operations and Effects of One Embodiment

In the opto-electric hybrid board 4 of the opto-electric transmission composite module 1, the driver element 6 is mounted on the one end portion in the longitudinal direction of the electric circuit board 11. When the driver element 6 generates heat, the heat first reaches the electric circuit board 11. The one edge 17 in the longitudinal direction of the electric circuit board 11 is located at one side in the longitudinal direction as compared to the one edge 12 in the longitudinal direction of the optical waveguide 10. Thus, the heat can be released to the other side in the thickness direction without the intervention of the optical waveguide 10. Thus, the reduction in the function of the optical element 5 can be suppressed.

Further, the electric circuit board 11 includes the metal supporting layer 19 and the one edge 17 in the longitudinal direction of the metal supporting layer 19 is located at one side in the longitudinal direction as compared to the one edge 12 in the longitudinal direction of the optical waveguide 10. Thus, the heat reaching the metal supporting layer 19 from the driver element 6 can effectively be released to the other side in the thickness direction without the intervention of the optical waveguide 10.

Further, the opto-electric transmission composite module 1 includes the heat dissipating layer 3, and the heat dissipating layer 3 is in contact with the other-side surface in the thickness direction of the electric circuit board 11, which is located at one side in the longitudinal direction as compared to the one edge 12 in the longitudinal direction of the optical waveguide 10. Thus, using the heat dissipating layer 3, the heat reaching the electric circuit board 11 from the driver element 6 can efficiently be released to the first wall 7 of the casing 2.

Furthermore, in the opto-electric transmission composite module 1, the optical element 5 and the driver element 6 are mounted on the second region 32 overlapping the metal supporting layer 19. Thus, the metal supporting layer 19 surely supports the optical element 5 and the driver element 6.

### <Variations>

In each of the following variations, the same members and steps as in the above-described embodiment are given the same numerical references and the detailed descriptions thereof are omitted. Further, the variations can have the same operations and effects as those of the embodiment unless especially described otherwise. Furthermore, the embodiment and the variations can appropriately be combined.

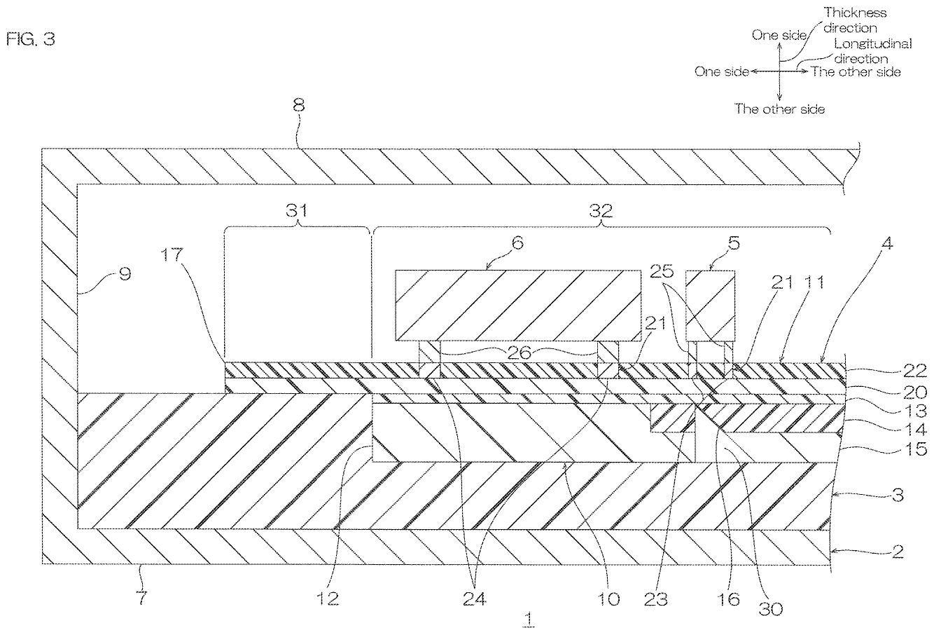

As illustrated in FIG. 3, in the opto-electric transmission composite module 1 of the variation, the electric circuit board 11 does not include the metal supporting layer 19. In other words, the electric circuit board 11 includes only the insulating base layer 20, the conductive layer 21, and the insulating cover layer 22.

The electric circuit board 11 has an outermost part at the other side in the thickness direction, and the outermost part is the insulating base layer 20. The insulating base layer 20 in the first region 31 is in contact with the heat dissipating layer 3. In detail, the other-side surface in the thickness direction of the insulating base layer 20—which is located at one side in the longitudinal direction as compared to the one edge 12 in the longitudinal direction of the optical waveguide 10, i.e., which is the other-side surface in the thickness direction of the electric circuit board 11 in the first region 31—is in contact with the one-side surface in the thickness direction of the heat dissipating layer 3.

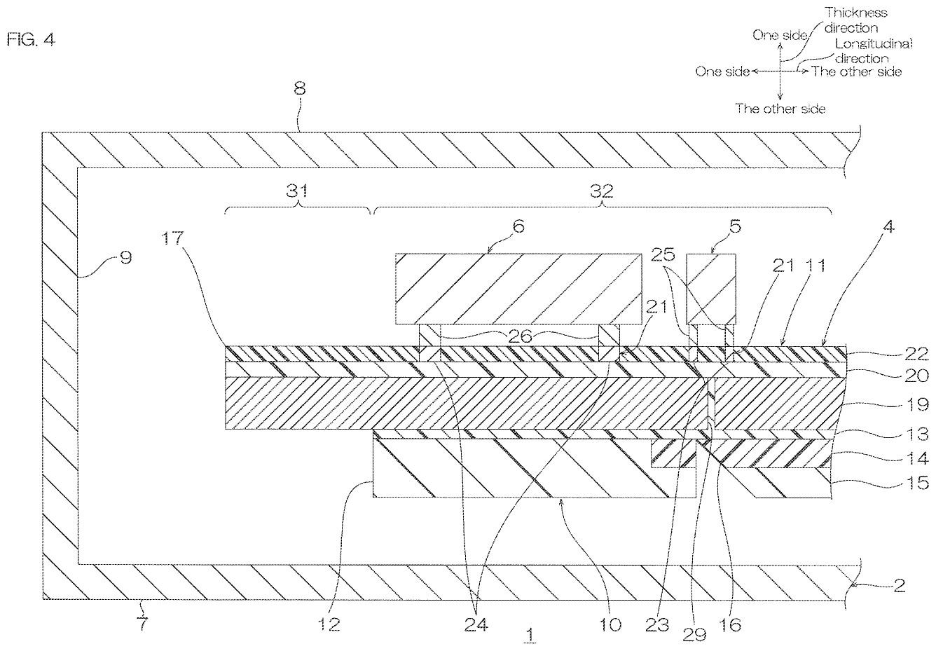

As illustrated in FIG. 4, the opto-electric transmission composite module 1 of the variation does not include the heat dissipating layer 3. In other words, the opto-electric transmission composite module 1 includes only the casing 2, the opto-electric hybrid board 4, the optical element 5, and the driver element 6.

The other-side surface in the thickness direction of the opto-electric hybrid board 4 is separated from the first wall 7 of the casing 2 by an interval in the thickness direction. A part of both the end portions in the width direction of the opto-electric hybrid board 4 is supported by both the side walls not illustrated in the casing 2.

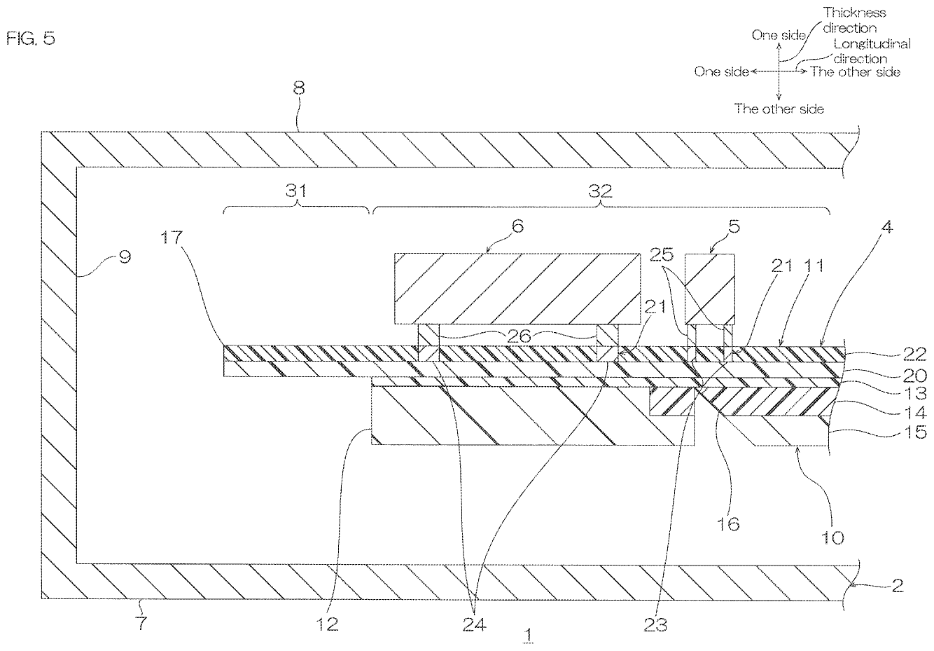

In illustrated in FIG. 5, the opto-electric transmission composite module 1 of the variation does not include the heat dissipating layer 3 and the electric circuit board 11 does not include the metal supporting layer 19. The structure in which the opto-electric transmission composite module 1 does not include the heat dissipating layer 3 is the same as that of FIG. 4. The structure in which the electric circuit board 11 does not include the metal supporting layer 19 is the same as that of FIG. 3.

Although not illustrated, the heat dissipating layer 3 may be in contact only with the electric circuit board 11 (preferably, the metal supporting layer 19) in the first region 31.

Although not illustrated, the electric circuit board 11 may not include the metal supporting layer 19, and the other-side surface in the thickness direction of the insulating base layer 20 in the first region 31 may be in contact with the heat dissipating layer 3.

Although not illustrated, the opto-electric transmission composite module 1 may be mounted on a printed wiring board. In the variation, the printed wiring board faces the electric circuit board 11 and is disposed at the one-side surface in the thickness direction of the electric circuit board 11. An opening portion penetrating in the thickness direction is formed in the printed wiring board, and the optical element 5 and the driver element 6 are accommodated in the opening portion.

While the illustrative embodiments of the present invention are provided in the above description, such is for illustrative purpose only and it is not to be construed as limiting in any manner Modification and variation of the present invention that will be obvious to those skilled in the art is to be covered by the following claims.

### INDUSTRIAL APPLICABILITY

The opto-electric hybrid board is used for opto-electric conversion modules.
1 opto-electric transmission composite module
2 casing
3 heat dissipating layer
4 opto-electric hybrid board
5 optical element
6 driver element
10 optical waveguide
11 electric circuit board
12 one edge in the longitudinal direction (optical waveguide)
17 one edge in the longitudinal direction (electric circuit board)
19 metal supporting layer
23 first terminal
24 second terminal

1. An opto-electric hybrid board comprising:
an optical waveguide extending in a longitudinal direction; and
an electric circuit board disposed on a one-side surface in a thickness direction of the optical waveguide and extending in the longitudinal direction, the electric circuit board including
a first terminal disposed on a one end portion in the longitudinal direction of a one-side surface in the thickness direction of the electric circuit board, the first terminal being for mounting an optical element, and
a second terminal disposed on the one end portion in the longitudinal direction of the one-side surface in the thickness direction of the electric circuit board, the second terminal being for mounting a driver element electrically connected with the optical element, wherein
one edge in the longitudinal direction of the electric circuit board is located at one side in the longitudinal direction as compared to one edge in the longitudinal direction of the optical waveguide.

2. The opto-electric hybrid board according to claim 1, wherein
the electric circuit board includes a metal supporting layer in the one end portion in the longitudinal direction, and
one edge in the longitudinal direction of the metal supporting layer is located at one side in the longitudinal direction as compared to the one edge in the longitudinal direction of the optical waveguide.

3. An opto-electric transmission composite module comprising:
the opto-electric hybrid board according to claim 1; and
a heat dissipating layer being in contact with the other-side surface in the thickness direction of the electric circuit board located at one side in the longitudinal direction as compared to the one edge in the longitudinal direction of the optical waveguide.

4. An opto-electric transmission composite module comprising:
the opto-electric hybrid board according to claim 2; and
a heat dissipating layer being in contact with the other-side surface in the thickness direction of the electric circuit board located at one side in the longitudinal direction as compared to the one edge in the longitudinal direction of the optical waveguide.
